(19) United States
(12) Patent Application Publication
(10) Pub. No.: US 2009/0159126 A1
(43) Pub. Date: Jun. 25, 2009

(54) INTEGRATED OPTICS FOR CONCENTRATOR SOLAR RECEIVERS

(75) Inventor: Hing Wah Chan, San Jose, CA (US)

Correspondence Address: THE MUELLER LAW OFFICE, P.C., 12951 Harwick Lane, San Diego, CA, 92130, US

(73) Assignee: SolFocus, Inc., Mountain View, CA (US)

(21) Appl. No.: 11/963,799

(22) Filed: Dec. 22, 2007

(51) Int. Cl. H01L 31/04

(52) U.S. Cl. 136/259

(57) ABSTRACT

A solar concentrator system, including at least two reflecting devices and a refracting lens, is provided. The reflecting devices focus light onto the lens which further concentrates the light on a solar cell. The lens increases the system's acceptance angle. In one embodiment the lens may be attached to the solar cell. In other embodiments, the lens is supported by a support structure, connecting element, and reflecting device.

### BACKGROUND OF TUE INVENTION

It is generally appreciated that one of the many known technologies for generating electrical power involves the harvesting of solar radiation and its conversion into direct current (DC) electricity. Solar power generation has already proven to be a very effective and “environmentally friendly” energy option, and further advances related to this technology continue to increase the appeal of such power generation systems. In addition to achieving a design that is efficient in both performance and size, it is also desirable to provide solar power units that are characterized by reduced cost and increased levels of conversion efficiency.

Solar concentrators are solar energy generators which increase the efficiency of conversion of solar energy to DC electricity. Solar concentrators which are known in the art utilize, for example, parabolic mirrors, Fresnel lenses, and immersion lenses for focusing the incoming solar energy, and heliostats for tracking the sun's movements in order to maximize light exposure. One type of solar concentrator, disclosed in U.S. Pat. No. 6,804,062, entitled “Nonimaging Concentrator Lens Arrays and Microfabrication of the Same”, combines a Fresnel lens and a single or double solid immersion lens system to focus solar energy onto a solar cell.

A new type of solar concentrator, disclosed in U.S. Patent Publication No. 2006/0266408, entitled “Concentrator Solar Photovoltaic Array with Compact Tailored Imaging Power Units” utilizes a front panel for allowing solar energy to enter the assembly, with a primary mirror and a secondary mirror to reflect and focus solar energy through an optical receiver, also referred to as a non-imaging concentrator, onto a solar cell. The surface area of the solar cell in such a system is much smaller than what is required for non-concentrating systems, for example less than 1% of the entry window surface area. Such a system has a high efficiency in converting solar energy to electricity due to the focused intensity of sunlight, and also reduces cost due to the decreased surface area of costly photovoltaic cells.

A similar type of solar concentrator is disclosed in U.S. Patent Publication No. 2006/0207650, entitled “Multi-Junction Solar Cells with an Aplanatic Imaging System and Coupled Non-Imaging Light Concentrator.” The solar concentrator design disclosed in this application uses a solid optic, out of which a primary mirror is formed on its bottom surface and a secondary mirror is formed in its upper surface. Solar radiation enters the upper surface of the solid optic, reflects from the primary mirror surface to the secondary mirror surface, and then enters a non-imaging concentrator which outputs the light onto a photovoltaic solar cell.

In these and other types of solar energy systems, a wider acceptance angle for the non-imaging concentrator improves the performance of the overall solar energy system. However, in the case of a non-imaging concentrator formed out of a solid dielectric, additional weight is added and multiplied by the plurality of concentrators used to form a solar collector panel. The higher panel weight may necessitate sturdier tracking hardware which raises overall system cost. The solid concentrator may also introduce energy loss thru violation of desired total internal reflection exacerbated at higher acceptance angles, potentially offsetting the non-imaging concentrator's improved efficiency. The non-imaging concentrator, whether it is a solid dielectric or a hollow reflecting design, also requires critical alignment to the optical axis which raises design and manufacturing complexity, again increasing cost.

Thus, the need exists for continuous improvement in simplified, low-cost solar concentrator energy systems which provide higher energy conversion efficiency.

### SUMMARY OF THE INVENTION

The present invention includes a refracting lens element which may be used in a solar energy system. The refracting lens element receives solar radiation from optical components, such as a primary mirror and a secondary mirror of a solar energy system, and outputs the solar radiation to a solar cell for conversion to electricity. In this invention, the refracting lens element is used to increase the acceptance angle of the solar concentrator optical system. In one embodiment, the refracting lens is attached to a receiving assembly, and the receiving assembly includes a solar cell. In another embodiment, the refracting lens is attached to a support structure used for the solar cell. In another embodiment, the refracting lens is attached to a solar cell during the wafer manufacturing of the solar cell. In another embodiment, the refracting lens is attached to the primary mirror.

### BRIEF DESCRIPTION OF THE DRAWINGS

FIG. 1 provides a cross-sectional view of an exemplary embodiment of a solar concentrator system;

FIG. 2 is a detail of the assembly of FIG. 1, showing a cross-sectional view of a first embodiment of a refracting lens element attached to a solar cell;

FIG. 3 is a detail of the assembly of FIG. 1, showing a cross-sectional view of a second embodiment of a refracting lens element attached to a solar cell support structure;

FIG. 4 is a detail of the assembly of FIG. 1, showing a cross-sectional view of a third embodiment of a refracting lens element indirectly attached to a solar cell support structure;

FIG. 5 is a detail of the assembly of FIG. 1, showing a cross-sectional view of a fourth embodiment of a refracting lens element attached to a primary mirror;

FIG. 6 is a detail of the assembly of FIG. 1, showing a cross-sectional view of a fifth embodiment of a refracting lens element indirectly attached to a primary mirror;

FIG. 7 shows a cross-sectional view of an alternative exempla embodiment of a solar concentrator system using a solid mirror optic attached to a refracting lens element;

FIG. 8 is a detail of the assembly of FIG. 7, showing a cross-sectional view of one embodiment of a solar cell with a support structure attached to a solid mirror optic;

FIG. 9 is a detail of the assembly of FIG. 7, showing a cross-sectional view of a second embodiment of a solar cell with a support structure attached to a refracting lens element;

FIG. 10 illustrates a cross-sectional view of another alternative exemplary embodiment of the solar concentrator system using a solid mirror optic and an indirectly attached refracting lens element; and

FIG. 11 is a detail of the assembly of FIG. 10, showing a cross-sectional view of one embodiment of a refracting lens element attached to a solar cell attached to a solid mirror optic; and

FIG. 12 is a detail of the assembly of FIG. 1, showing a cross-sectional view of a sixth embodiment of a refracting lens element attached to a solar cell.

### DETAILED DESCRIPTION OF THE EMBODIMENTS

Reference now will be made in detail to embodiments of the disclosed invention, one or more examples of which are illustrated in the accompanying drawings. Each example is provided by way of explanation of the present technology, not limitation of the present technology. In fact, it will be apparent to those skilled in the art that modifications and variations can be made in the present technology without departing from the spirit and scope thereof. For instance, features illustrated or described as part of one embodiment may be used on another embodiment to yield a still further embodiment. Thus, it is intended that the present subject matter covers such modifications and variations as come within the scope of the appended claims and their equivalents.

This invention includes a refracting lens element used in combination with mirrors to concentrate solar energy onto a solar cell to generate DC electrical power. The refracting lens element increases the acceptance angle for the solar concentrator system improving efficiency when the system is not in perfect alignment with the sun. The refracting lens element is smaller, lighter, and easier to align than previously described non-imaging concentrators. The current invention improves concentrator system efficiency at higher acceptance angles by eliminating the problem of light leakage thru violation of total internal reflection which some non-imaging concentrators may suffer.

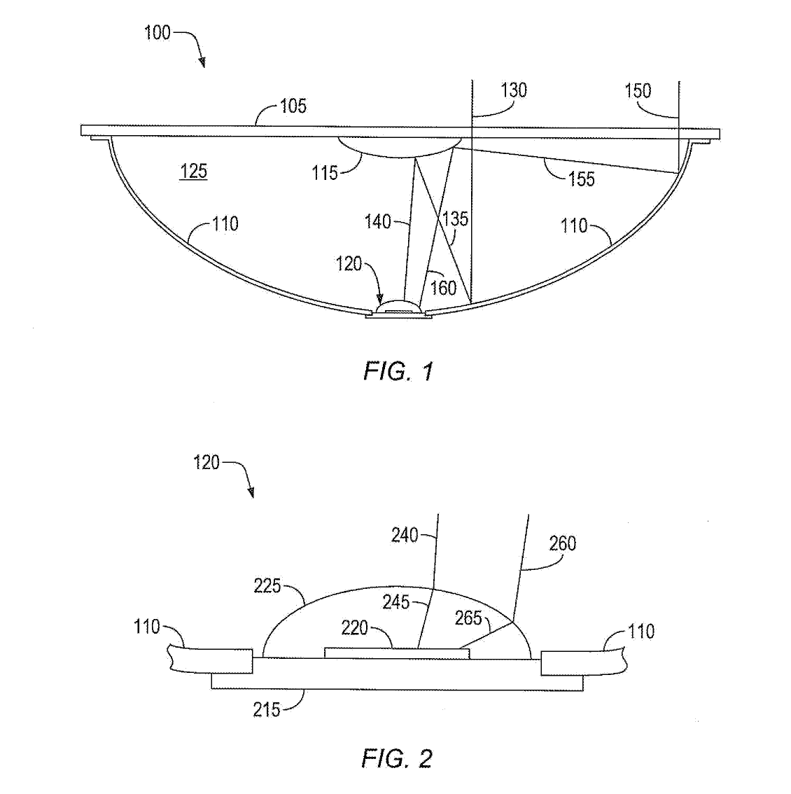

With reference to FIG. 1, a simplified a cross-sectional view of an exemplary solar concentrator system 100 is shown. The main optical elements of the concentrator system 100 are a protective front panel 105, a primary mirror 110, a secondary mirror 115, and a receiver assembly 120. Note that for commercial application, the single concentrator system 100 would typically be replicated to form an array of adjoining concentrator units as part of a complete solar panel. Protective front panel 105 is a substantially planar surface, such as a window or other transparent covering, which provides structural integrity for the concentrator system and protection for other components thereof. In one embodiment, front panel 105 is composed of glass; however, any type of transparent or transmissive planar sheet, such as polycarbonate, may be suitable for use in the concentrator system. Sunlight, represented by a pair of ray elements 130 and 150, enters the concentrator system 100 through front panel 105 and reflects off of primary mirror 110 to secondary mirror 115 as shown by a pair of corresponding ray elements 135 and 155. Secondary mirror 115 further reflects and focuses the sunlight onto receiver assembly 120 as shown by a pair of corresponding ray elements 140 and 160. In one embodiment, receiver assembly 120 houses elements to be described below that intensify and convert the sunlight into electrical energy.

In reference still to FIG. 1, primary mirror 110 and secondary mirror 115 are substantially co-planar, at least a portion of both mirrors being in contact will front panel 105. In the depicted configuration, primary mirror 110 is generally circular and in contact will the front panel. Primary mirror 110 is preferably a second surface mirror using, for example, silver, and slump-formed from soda-lime glass. In one exemplary embodiment, primary mirror 110 may have a diameter of approximately 280 mum and a depth of approximately 70 mm. Secondary mirror 115 is generally circular, and may be a first surface mirror using silver and a passivation layer formed on a substrate of soda-lime glass. In one embodiment, secondary mirror 115 may have a diameter of approximately 50 mm. The primary mirror 110 and secondary mirror 115 define an inter-mirror region 125 thru which the sunlight and corresponding ray elements 130, 135, 140, 150, 155, and 160 are transmitted. Inter-mirror region 125 may be filled with air, inert gas, or evacuated to a partial vacuum, or any combination thereof.

FIG. 2 provides a closer view of one embodiment of receiver assembly 120 and its attachment to primary mirror 110. The embodiment shown in FIG. 2 includes a support structure 215 which supports a solar cell 220 and a refracting lens element 225 which is directly attached to the solar cell 220. Support Structure 215 may be a heat sink. Support structure 215 is attached to primary mirror 110 by conventional means known by those familiar with the art. For example, structure 215 can be directly attached to primary mirror 110 by adhesive polymers, soldering or frit bonding. Indirect attachment can also be used when a mechanical stable outer frame is used to hold the primary mirror 110 and the secondary mirror 115.

Incoming concentrated sunlight from the secondary mirror, represented by a pair of ray elements 240 and 260, is focused onto refracting lens element 225. Refracting lens element 225 is made of a denser material than the inter-mirror region and thus the refractive index of refracting lens element 225 is higher than the inter-mirror region with refractive index equal to that of air. Refracting lens element 225 then transmits the solar radiation, as taught in further detail below, to solar cell 220 which converts the sunlight into electrical energy.

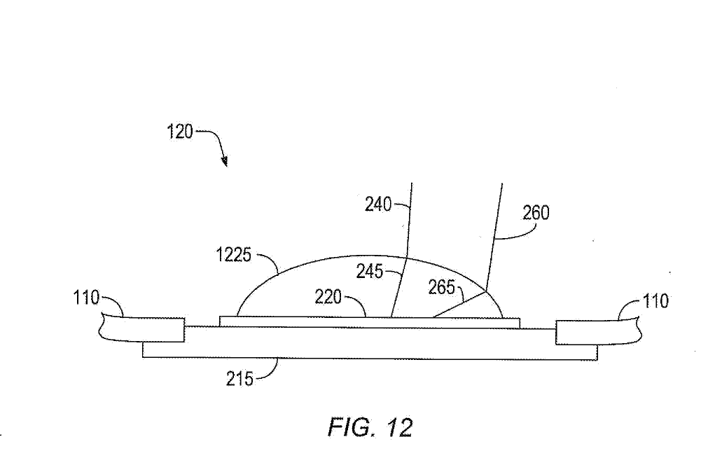

Again referring to FIG. 2, the refracting lens element 225 encapsulates solar cell 220 protecting it from the environment of the inter-mirror region. In an alternative embodiment (described below in FIG. 12), the refracting lens element may be in direct contact with the solar cell and not encapsulating the edges of the solar cell.

Still referring to FIG. 2, the incoming concentrated sunlight from the secondary mirror can be divided into two components. The first component is the radiation represented by ray 240 which is focused in a path aligned to directly hit solar cell 220 even if refracting lens element, 225 was absent from the system. The refracting lens element is designed to transmit the first component of radiation to solar cell 220 as represented by a refracted ray 245 corresponding to ray 240. The second component of radiation is represented by ray 260 which is focused in a path aligned not to directly hit solar cell 220 if refracting lens element 225 was absent from the system. Refracting lens element 225 is designed to be larger than solar cell 220 and of such shape as to refract rays of the second radiation component back onto a path to hit the solar cell as represented by a refracted ray 265 corresponding to ray 260. The second component radiation may represent rays which are generated when the solar concentrator system is not in perfect alignment with the sun and thus refracting lens element 225 increases the acceptance angle of the solar concentrator optical system and improves efficiency even when tracking error is present or imprecise optical alignment within the system occurs. Wider acceptance angle lowers system cost by enabling optimized tradeoffs between the cost of accurate mechanical tracking equipment, optical component precision, and energy conversion efficiency.

The addition of an anti-reflection (AR) coating on the surfaces of retracting lens element 225 will further increase the overall efficiency of the system. An AR coating mitigates interface reflection losses which may be introduced by the addition of the refracting lens element. An AR coating may be applied to either or each surface of the refracting lens element, particularly to the input surface, and may also be applied to the exit surface facing solar cell 220.

Since the physical aspect ratio or width divided by height of the dimensions of refracting lens element 225 is high compared to non-imaging concentrators, the refracting lens element of the present invention is easier to attach and align with the rest of the solar concentrator elements. The higher aspect ratio of refracting lens element 225 reduces the problem of loss of total internal reflection which is a problem non-imaging concentrators may have at higher acceptance angles. The smaller size and weight of the refracting lens element compared to solid dielectric non-imaging concentrators reduces the cost of mechanical tracking hardware and provides a benefit that is multiplied by the number of arrayed adjoining concentrator units forming a complete solar panel.

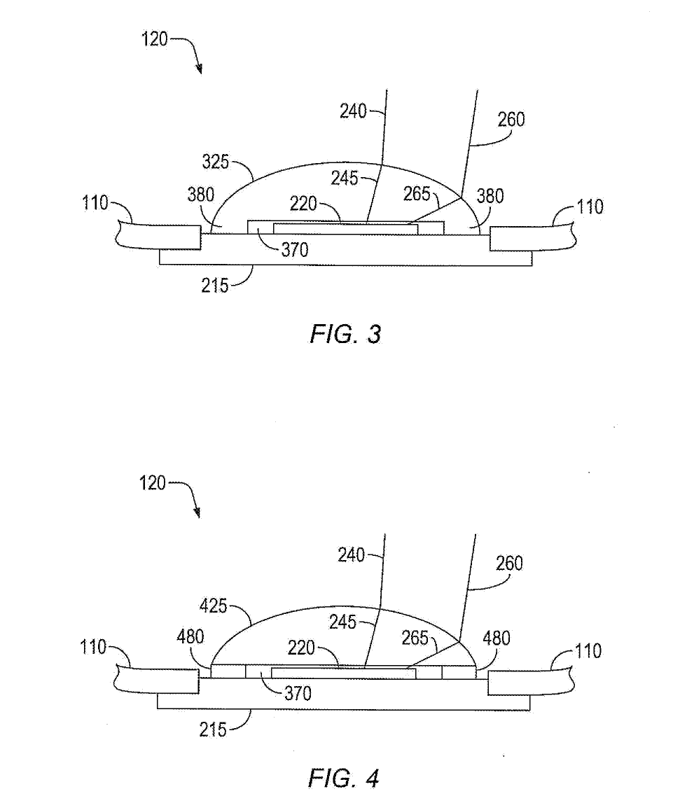

In FIG. 3, a cross-sectional view of an alternative embodiment of receiver assembly 120 and its attachment to primary mirror 110 is shown. The same elements of a primary mirror 110, support structure 215, solar cell 220, ray elements 240 and 260, and refracted rays 245 and 265 are shown providing the same functions and features as described with reference to FIG. 2. In the view provided in FIG. 3, however, a refracting lens element 325 which is not directly attached to solar cell 220 is shown. Refracting lens element 325 is made with a recess such that it is supported upon support structure 215 by an extension 380 of lens element 325 which extends entirely around the perimeter of retracting lens element 325 such that solar cell 220 is in close proximity to the exit surface of refracting lens element 325. The retracting lens element 325 together with its extension 380, and support structure 215 enclose a cavity 370 over solar cell 220. Cavity 370 may be filled with air, inert gas, evacuated to a partial vacuum, any combination thereof, or filled with index matching get, oil or other clear materials with the same index as the lens material. Another alternate embodiment may provide gaps in extension 380 or use a plurality of separate extensions 380 to attach refracting lens element 325 to support structure 215 in which case cavity 370 is exposed to the environment of the inter-mirror region and is filled with that same material. Extension 380 of lens element 325 is attached to support structure 215 by means known to those familiar with the art. In other respects, lens element 325 is designed and functions in similar fashion to lens element 225 shown in FIG. 2.

FIG. 4 illustrates a cross-sectional view of another alternative embodiment of receiver assembly 120 and its attachment to primary mirror 110. The same elements of a primary mirror 110, support structure 215, solar cell 220, ray elements 240 and 260, and refracted rays 245 and 265 are shown providing the same functions and features as described with reference to FIG. 2. Also shown in FIG. 4 is cavity 370 which is described in FIG. 3. In the view provided in FIG. 4, however, a refracting lens element 425 is indirectly attached to support structure 215 by a connecting element 480 which may extend entirely around the perimeter of refracting lens element 425 or in an alternative embodiment uses a plurality of separate pieces. Connecting element 480 may be, for example, fritted glass, a Kovar® ring, or other materials that match the thermal expansion coefficient of refractive element 425.

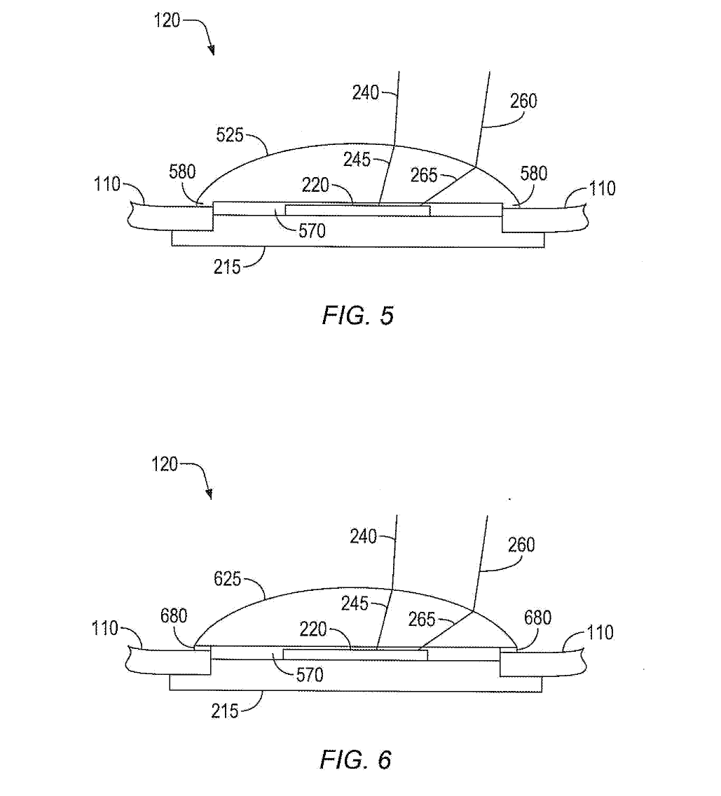

FIG. 5 illustrates a cross-sectional view of an alternative embodiment of receiver assembly 120 and its attachment to primary mirror 110. The same elements described with reference to FIG. 2 of a primary mirror 110, support stricture 215, solar cell 220, ray elements 240 and 260, and refracted rays 245 and 265 are shown providing the same functions and features. Also shown in FIG. 5 is a cavity 570 similar to but possibly longer than cavity 370 described with reference to FIG. 3. In the view provided in FIG. 5, however: a refracting lens element 525 is made with a recess such that it is supported upon primary mirror 110 by an extension 580 of the lens element which extends entirely around the perimeter of retracting lens element 525 or by a plurality of separate extensions. Extension 580 of lens element 525 is attached to primary mirror 110 by means known to those familiar with the art. In an alternative embodiment (not shown), the lens element's extension is omitted and instead, the lens element is directly attached to the primary mirror. These embodiments provide a more efficient concentrator design because the diameter of the refracting, lens element is no longer constrained by the size of the support structure or its attachment with the primary mirror thus eliminating optically inactive surfaces.

In FIG. 6, a cross-sectional view of another alternative embodiment of receiver assembly 120 and its attachment to primary mirror 110 is shown. The same elements of a primary mirror 110, support structure 215, solar cell 220, ray elements 240 and 260, and refracted rays 245 and 265 are shown providing the same functions and features as described with reference to FIG. 2. Also shown in FIG. 6 is cavity 570 described with reference to FIG. 5. In the view provided in FIG. 6, however, a refracting lens element 625 is indirectly attached to primary mirror 110 by a connecting element 680 which may extend entirely around the perimeter of refracting lens element 625 or in an alternative embodiment uses a plurality of separate pieces 680.

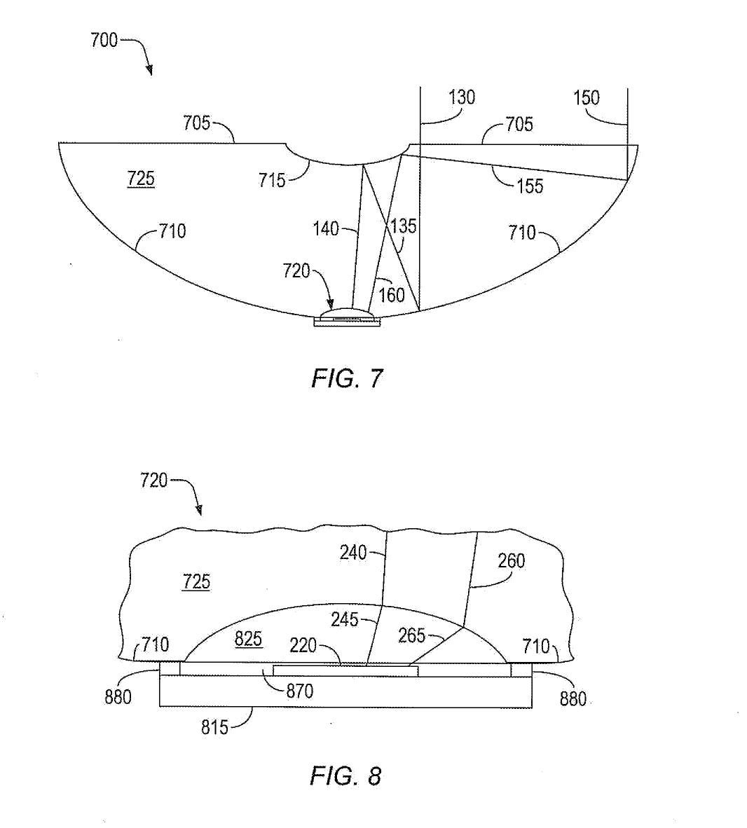

Moving to FIG. 7, a cross-sectional view of an alternative exemplary solar concentrator system 700 is shown. The main optical elements of the concentrator system 700 are a transmissive entrance surface 705, a primary mirror 710, a secondary mirror 715, and a receiver assembly 720 and are designed to function in like manner to concentrator system 100 as described with reference to FIG. 1 except they are all formed from a solid dielectric material 725. In one embodiment, the solid dielectric material 725 is composed of glass; however, any type of transparent or transmissive material, such as polycarbonate, may be suitable for use in the concentrator system. In one embodiment the transmissive entrance surface 705 is coated with anti-reflective coatings and in another embodiment the primary and secondary mirrors 710 and 715 respectively are formed of reflective coatings known to those familiar with the art. The same ray elements 130, 135, 140, 150, 155, and 160 given set forth in FIG. 1 are shown in FIG. 7 and are used to represent how sunlight is concentrated onto receiver assembly 720 in the same manner as described with reference to FIG. 1. In one embodiment, receiver assembly 720 houses elements to be described below that intensify and convert the sunlight into electrical energy.

FIG. 8 presents a closer view of one embodiment of receiver assembly 720 and its attachment to primary mirror 710 and solid dielectric material 725. The same elements of a solar cell 220, ray elements 240 and 260, and refracted rays 245 and 265 are shown providing the same functions and features as described with reference to FIG. 2. In the view provided in FIG. 8, however, a refracting lens element 825 which is not directly attached to solar cell 220 is shown. Refracting lens element 825 is, instead, directly attached to solid dielectric material 725. Refracting lens element 825 is made of a material with a higher index of refraction than solid dielectric material 725. Solar cell 220 is supported by a support structure 815 which is attached to primary mirror 710 by a connecting element 880 such that solar cell 220 is in close proximity to the exit surface of refracting lens element 825. In this embodiment, refracting lens element 825 together with connecting element 880 and support structure 815 enclose a cavity 870 over solar cell 220. Cavity 870 may be filled with air, inert gas, evacuated to a partial vacuum, any combination thereof or filled with other material of desirable optical matching property to reduce Fresnel loss. Connecting element 880 is attached to support structure 815 and primary mirror 710 by means known to those familiar with the art. In other respects the lens element 825 is designed and functions in similar fashion to the lens described above.

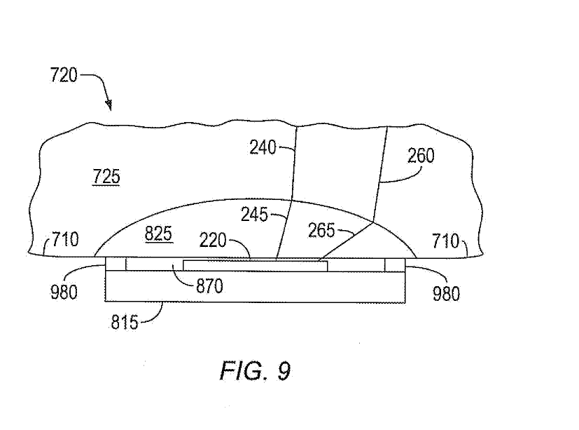

FIG. 9 illustrates a closer view of one embodiment of receiver assembly 720 and its attachment to primary mirror 710 and solid dielectric material 725. The same elements of a solar cell 220, ray elements 240 and 260, and refracted rays 245 and 265 are shown providing the same functions and features as described with reference to FIG. 2. The same elements of refracting lens element 825, support stricture 815, and cavity 870 are shown providing the same functions and features as described with reference to FIG. 8. However, FIG. 9 shows a connecting element 980 which is attached to support structure 815 and refracting lens element 825 by means known to those familiar with the art, which is in contrast to the embodiment described with reference to FIG. 8 where the connecting element is attached to the primary mirror instead of the refracting lens element.

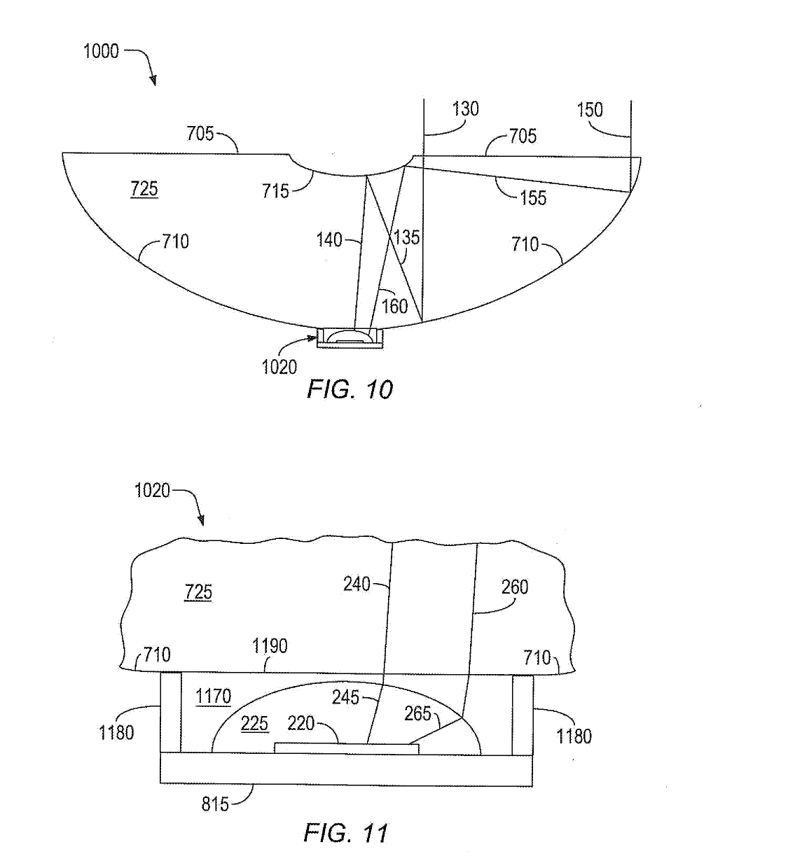

FIG. 10 shows a cross-sectional view of an alternative exemplary solar concentrator system 1000. The same elements of a transmissive entrance surface 705, primary mirror 710, secondary mirror 715, ray elements 130, 135, 140, 150, 155, and 160, and a solid dielectric material 725 are shown providing the same functions and features as described with reference to FIG. 7. In the view provided in FIG. 10, however, a receiver assembly 1020 is attached to the exterior of solid dielectric material 725.

In FIG. 11, a closer view of one embodiment of receiver assembly 1020 and its attachment to primary mirror 710 and solid dielectric material 725 is shown. The same elements of solar cell 220, refracting tens element 225, ray elements 240 and 260, and refracted rays 245 and 265 are shown providing the same functions and features as described with reference to FIG. 2. The same support structure 815 is showing providing the same function and feature as described with reference to FIG. 8. The same elements of primary mirror 710, and solid dielectric material 725 are shown providing the same functions and features as described with reference to FIG. 10. In the view provided in FIG. 11, however, refracting lens element 225 is not directly attached to solid dielectric material 725. Instead. FIG. 11 shows support structure 815 supporting solar cell 220 and refracting lens element 225. Support structure 815 is attached to primary mirror 710 by means of a collar 1180 such that refracting lens element 225 is in close proximity to an exit surface 1190 of solid dielectric material 725. The collar 1180 is attached to support structure 815 and primary mirror 710 by means known to those familiar with the art. In an alternative embodiment (not shown), the collar may be attached directly to the exit surface. Refracting lens element 225, support structure 815, collar 1100, and exit surface 1190 enclose a cavity 1170 over refracting lens element 225. Cavity 1170 may be filled with air, inert gas, evacuated to a partial vacuum, any combination thereof, or filled with other material of desirable optical matching property to reduce Fresnel loss at the optical surfaces. Optical ray elements 240 and 260 may be refracted slightly at the exit surface 1190 but such refraction would be minor in comparison to that occurring at the surface of refracting lens element 225. Thus, the introduction of the new optical surface at exit surface 1190 will not substantially alter the path of rays 240 and 260 so the optical function of receiver assembly 1020 is still similar to that described with reference to FIG. 2.

Referring to FIG. 12, a cross-sectional view of an alternative embodiment of receiver assembly 120 and its attachment to primary mirror 110 is shown. The same elements of a primary mirror 110 support structure 215, solar cell 220, ray elements 240 and 260, and refracted rays 245 and 265 are shown providing the same functions and features as described with reference to FIG. 2. In the view provided in FIG. 12, however, a refracting lens element 1225 is attached to solar cell 220 during the solar cell manufacturing process such that the edge of the refracting lens element is coupled to the surface of solar cell 220 instead of overlapping the edge of the solar cell. Refracting lens element 1225 is placed while the solar cell is still in water form on substantially all the solar cell die on that wafer as part of a batch wafer semiconductor processing operation. In an alternative method, the refracting lens element is placed only on those solar cell die that are identified as good die on the wafer. The refracting lens element may be formed by dispensing onto the solar cell die a measured quantity of silicone material or other clear liquid material with the desired high index optical properties that is also compatible with the batch wafer manufacturing process. The liquid is subsequently hardened by curing and takes the desired shape, properties, and function of a refracting lens as element 1225 which are similar to refracting lens element 225 as described with, reference to FIG. 2 (also referred to as an immersion lens). After the refracting lens element is cured sufficiently hard, the solar cell die, each with a fully formed refracting lens element attached, are separated from each other (or singulated). Refracting lens element 1225 is smaller in size than solar cell 220 so that singulation can be properly accomplished. The batch formation and placement of refracting lens element 1225 upon solar cell 220 during the solar cell wafer processing lowers manufacturing cost compared to forming the lens separately and subsequently placing the lens during manufacture of the receiver assembly 120.

The replacement of a non-imaging concentrator element with a refracting lens element thus improves the performance of a solar concentrator. It may be possible to use non-planar materials and surfaces with the techniques disclosed herein. Other embodiments can use optical or other components for focusing any type of electromagnetic energy such as infrared, ultraviolet, radio-frequency, etc. There may be other applications for the fabrication method and apparatus disclosed herein, such as in the fields of light emission or sourcing technology (e.g., fluorescent lighting using a trough design, incandescent, halogen, spotlight, etc.) where the light source is put in the position of the photovoltaic cell. In general, any type of suitable cell, such as a photovoltaic cell, concentrator cell or solar cell can be used. In other applications it may be possible to use other energy such as any source of photons, electrons or other dispersed energy that can be concentrated. Additional reflectors and other non-imaging optical devices may be used with the disclosed configuration. Also, the disclosed configuration of the reflecting objects may be rearranged to concentrate solar rays through the disclosed lens and onto the solar cell.

While the specification has been described in detail with respect to specific embodiments of the invention, it will be appreciated that those skilled in the art upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention.

What is claimed is:

1. A solar concentrator system, comprising:
a first reflective mirror capable of collecting solar radiation, said first mirror concentrating said solar radiation into a first region;
a second reflective mirror located substantially in said first region, said second mirror aligned with said first mirror to receive said concentrated solar radiation from said first mirror, said second mirror further concentrating said solar radiation into a second region;
a refracting optical device located substantially in said second region, said refracting device aligned with said second mirror to receive said further concentrated solar radiation from said second mirror, said refracting device further concentrating said solar radiation into a third region; and
a solar cell capable of converting solar radiation into electricity, said cell created with a wafer manufacturing process, said cell located substantially in said third region, said cell aligned below said refracting device to receive said further concentrated solar radiation from said refracting device, said cell converting said concentrated solar radiation into electricity.

2. The solar energy concentrator system of claim 1, wherein said refracting device is aligned onto said solar cell during said wafer manufacturing process, and said refracting device being smaller than said cell.

3. The solar energy concentrator system of claim 1, further comprising:
a substantially planar surface;
a perimeter on said first mirror wherein at least a portion of said perimeter is coupled to said planar surface;
an open center region on said first mirror wherein said open region is substantially in said second region; and
a mounting surface on said second mirror wherein at least a portion of said mounting surface is coupled to said planar surface.

4. The solar energy concentrator system of claim 1, further comprising a support structure, wherein said solar cell is coupled to said support structure, said support structure is coupled to said first mirror, and said refracting optical device is coupled to said solar cell.

5. The solar energy concentrator system of claim 1, further comprising a support structure, wherein said solar cell is coupled to said support structure, said support structure is coupled to said first mirror, and said refracting optical device is coupled to said support structure.

6. The solar energy concentrator system of claim 1, wherein said retracting optical device is coupled to said first mirror.

7. The solar energy concentrator system of claim 1, wherein said refracting optical device is comprised of silicone.

8. The solar energy concentrator system of claim 1, wherein said refracting optical device is an immersion lens.

9. The solar energy concentrator system of claim 1, further comprising a solid dielectric material, wherein said first and said second mirrors are coupled to said solid dielectric material in a solid unit.

10. The solar energy concentrator system of claim 9 wherein said refracting optical device is coupled to said solid dielectric material.

11. The solar energy concentrator system of claim 10 wherein said refracting optical device is directly attached to said solid dielectric material.

12. A method of concentrating solar radiation upon a solar cell and generating electricity, comprising:
first concentrating solar radiation into a first region using a first reflective mirror;
second concentrating said solar radiation into a second region using a second reflective mirror being located substantially in said first region, said second mirror aligning with said first mirror and receiving said first concentrated solar radiation from said first mirror;
third concentrating said solar radiation into a third region using a refracting optical device being located substantially in said second region, said refracting device aligning with said second mirror and receiving said second concentrated solar radiation from said second mirror; and
converting solar radiation into electricity with a solar cell located substantially in said third region, said solar cell being aligned with said refracting device, and receiving said third concentrated solar radiation from said refracting device.

13. The method of claim 12 further comprising, creating said solar cell with a wafer manufacturing process, aligning said refracting device onto said solar cell during said wafer manufacturing process, wherein said refracting device is created smaller than said solar cell.

14. The method of claim 12, further comprising, attaching said solar cell to a support structure, coupling said support structure to said first mirror, and coupling said refracting optical device to said solar cell.

15. The method of claim 12, wherein said solar cell is coupled to a support structure, and said refracting optical device is coupled to said support structure.

16. The method of claim 12, wherein said refracting optical device is coupled to said first mirror.

17. The method of claim 12, wherein said first and said, second mirrors are coupled to a solid dielectric material forming a solid unit.

18. The method of claim 12, further comprising, creating said refracting optical device using, a liquid material, and curing hard said material to form an immersion lens.

19. The method of claim 17, wherein said refracting optical device is coupled to said solid dielectric material.

20. The method of claim 18, wherein said liquid material is comprised of silicone.
